(19) United States
(12) Patent Application Publication
(10) Pub. No.: US 2026/0344448 A1
(43) Pub. Date: Oct. 29, 2026

(54) HIGH FREQUENCY DEVICE

(71) Applicant: SUMITOMO ELECTRIC DEVICE INNOVATIONS, INC., Kanagawa (JP)

(72) Inventor: Nobuhisa KAMATA, Osaka (JP)

(21) Appl. No.: 19/629,536

(22) Filed: Mar. 26, 2026

(30) Foreign Application Priority Data
Apr. 23, 2025 (JP) 2025-071538

(51) Int. Cl. H10W 44/20; H03F 1/02; H03F 1/30; H03F 1/56

(52) U.S. Cl. CPC H10W 44/234; H03F 1/0288; H03F 1/301; H03F 1/565; H10W 44/243

(57) ABSTRACT

A high frequency device includes a base having an electrical conductivity, a semiconductor chip mounted on the base and configured to process a high frequency signal, a harmonic control circuit including a first capacitor mounted on the base and configured to process a harmonic of the high frequency signal, an insulating layer provided on the base so as to cover the semiconductor chip and the first capacitor, and a line provided on the insulating layer and configured to transmit the high frequency signal. The first capacitor is shunt-connected to the line.

### CROSS REFERENCE TO RELATED APPLICATIONS

This application claims priority to Japanese Patent Application No. 2025-071538 filed on Apr. 23, 2025, the entire contents of which are incorporated herein by reference.

### TECHNICAL FIELD

The present disclosure relates to a high frequency device.

### BACKGROUND

A high-frequency device is known in which a semiconductor chip and a passive chip are mounted on a base, an insulating layer covering the semiconductor chip and the passive chip is provided, and an electronic component is mounted on the insulating layer (see patent literature: Japanese Unexamined Patent Application Publication No. 2023-133677).

### SUMMARY

A high frequency device according to an embodiment of the present disclosure includes a base having an electrical conductivity, a semiconductor chip mounted on the base and configured to process a high frequency signal, a harmonic control circuit including a first capacitor mounted on the base and configured to process a harmonic of the high frequency signal, an insulating layer provided on the base so as to cover the semiconductor chip and the first capacitor, and a line provided on the insulating layer and configured to transmit the high frequency signal. The first capacitor is shunt-connected to the line.

A high frequency device according to an embodiment of the present disclosure includes a base having an electrical conductivity, a semiconductor chip mounted on the base and configured to process a high frequency signal, a first capacitor mounted on the base, an insulating layer provided on the base so as to cover the semiconductor chip and the first capacitor, a line provided on the insulating layer and configured to transmit the high frequency signal, and a second capacitor provided on the insulating layer and having a capacitance larger than a capacitance of the first capacitor. The first capacitor and the second capacitor are shunt-connected to the line.

### BRIEF DESCRIPTION OF THE DRAWINGS

FIG. 1 is a circuit diagram of a high frequency device according to a first embodiment.

FIG. 2 is a plan view of a high frequency device according to a first embodiment.

FIG. 3 is a plan view of a high frequency device according to a first embodiment.

FIG. 4 is an A-A cross-sectional view of FIGS. 2 and 3.

FIG. 5 is a B-B cross-sectional view of FIGS. 2 and 3.

FIG. 6 is a plan view of a high frequency device according to a first comparative embodiment.

FIG. 7 is a plan view of a high frequency device according to a first comparative embodiment.

FIG. 8 is an A-A cross-sectional view of FIGS. 6 and 7.

FIG. 9 is a C-C cross-sectional view of FIGS. 6 and 7.

FIG. 10 is a circuit diagram of a high frequency device according to a first comparative embodiment.

FIG. 11 is a plan view of a high frequency device according to a second embodiment.

FIG. 12 is a plan view of a high frequency device according to a second embodiment.

FIG. 13 is a A-A cross-sectional view of FIGS. 11 and 12.

FIG. 14 is a circuit diagram of a high frequency device according to a third embodiment.

FIG. 15 is a plan view of a high frequency device according to a third embodiment.

FIG. 16 is a plan view of a high frequency device according to a third embodiment.

FIG. 17 is a C-C cross-sectional view of FIGS. 15 and 16.

FIG. 18 is a plan view of a high frequency device according to a second comparative embodiment.

FIG. 19 is a circuit diagram of a high frequency device according to a second comparative embodiment.

FIG. 20 is a circuit diagram of an amplifier circuit according to a fourth embodiment.

### DETAILED DESCRIPTION

The high frequency device includes a semiconductor chip that is configured to process a high frequency signal, a harmonic control circuit that is configured to process a harmonic of the high frequency signal, and the like. It is not known which of the capacitors of the high frequency device is preferably mounted on the base.

It is desirable to provide a high frequency device capable of improving high frequency characteristics.

According to the present disclosure, a high frequency device capable of improving high frequency characteristics can be provided.

### Description of Embodiments of Present Disclosure

First, embodiments of the present disclosure will be listed and described.
(1) A high frequency device according to an embodiment of the present disclosure includes a base having an electrical conductivity, a semiconductor chip mounted on the base and configured to process a high frequency signal, a harmonic control circuit including a first capacitor mounted on the base and configured to process a harmonic of the high frequency signal, an insulating layer provided on the base so as to cover the semiconductor chip and the first capacitor, and a line provided on the insulating layer and configured to transmit the high frequency signal. The first capacitor is shunt-connected to the line. This reduces the parasitic inductance and improves the high frequency characteristics of the harmonic control circuit.
(2) In the above (1), the high frequency device may further include a first wiring layer provided on the insulating layer, and a first through electrode penetrating the insulating layer. The first capacitor may include a dielectric substrate, a first electrode provided on the dielectric substrate, and a second electrode provided under the dielectric substrate and bonded to the base. The first wiring layer may be electrically connected to the first electrode by the first through electrode. This reduces the parasitic inductance and improves the high frequency characteristics of the harmonic control circuit.
(3) In the above (2), the high frequency device may further include a second through electrode penetrating the insulating layer. The semiconductor chip may include a pad to which the high frequency signal is input or from which the high frequency signal is output. The first wiring layer may be electrically connected to the pad by the second through electrode. This reduces the parasitic inductance and improves the high frequency characteristics of the harmonic control circuit.
(4) In any one of the above (1) to (3), the harmonic control circuit may include a plurality of capacitors connected in series between the line and the base. The first capacitor may be a capacitor closest to the base among the plurality of capacitors. The plurality of capacitors may include the first capacitor and one or more capacitors mounted on the insulating layer. This enables downsizing and improvement of high frequency characteristics.
(5) In any one of the above (1) to (4), the high frequency device may further include an input terminal to which the high frequency signal is input, an output terminal from which the high frequency signal processed by the semiconductor chip is output, and a matching circuit including a second capacitor shunt-connected to the line and mounted on the insulating layer, the matching circuit being configured to match an impedance between the semiconductor chip and one of the input terminal or the output terminal at a frequency of the high frequency signal. This enables downsizing and improvement of high frequency characteristics.
(6) In the above (5), the high frequency device may further include a second wiring layer provided on the insulating layer and configured to transmit the high frequency signal, and a third wiring layer provided on the insulating layer and electrically connected to the base. The second capacitor may have a first end bonded onto the second wiring layer and a second end bonded onto the third wiring layer. This enables downsizing and improvement of high frequency characteristics.
(7) In any one of the above (1) to (4), the high frequency device may further include an input terminal to which the high frequency signal is input, an output terminal from which the high frequency signal processed by the semiconductor chip is output, and a matching circuit including a second capacitor mounted on the base, the matching circuit being configured to match an impedance between the semiconductor chip and one of the input terminal or the output terminal at a frequency of the high frequency signal. The insulating layer may be provided on the base so as to cover the semiconductor chip, the first capacitor, and the second capacitor. This enables downsizing and improvement of high frequency characteristics.
(8) In any one of the above (1) to (7), the high frequency device may further include a third capacitor connected in series to the line and mounted on the insulating layer. This enables downsizing and improvement of high frequency characteristics.
(9) A high frequency device according to an embodiment of the present disclosure includes a base having an electrical conductivity, a semiconductor chip mounted on the base and configured to process a high frequency signal, a first capacitor mounted on the base, an insulating layer provided on the base so as to cover the semiconductor chip and the first capacitor, a line provided on the insulating layer and configured to transmit the high frequency signal, and a second capacitor provided on the insulating layer and having a capacitance larger than a capacitance of the first capacitor. The first capacitor and the second capacitor are shunt-connected to the line. This enables downsizing and improvement of high frequency characteristics.
(10) In any one of the above (1) to (9), the semiconductor chip may include an amplifier configured to amplify the high frequency signal. This can improve the high frequency characteristics of the amplifier.

### Details of Embodiments of Present Disclosure

Specific examples of a high frequency device according to an embodiment of the present disclosure will be described below with reference to the drawings. The present disclosure is not limited to these examples, but is defined by the scope of the claims, and is intended to include all modifications within the meaning and scope equivalent to the scope of the claims.

### First Embodiment

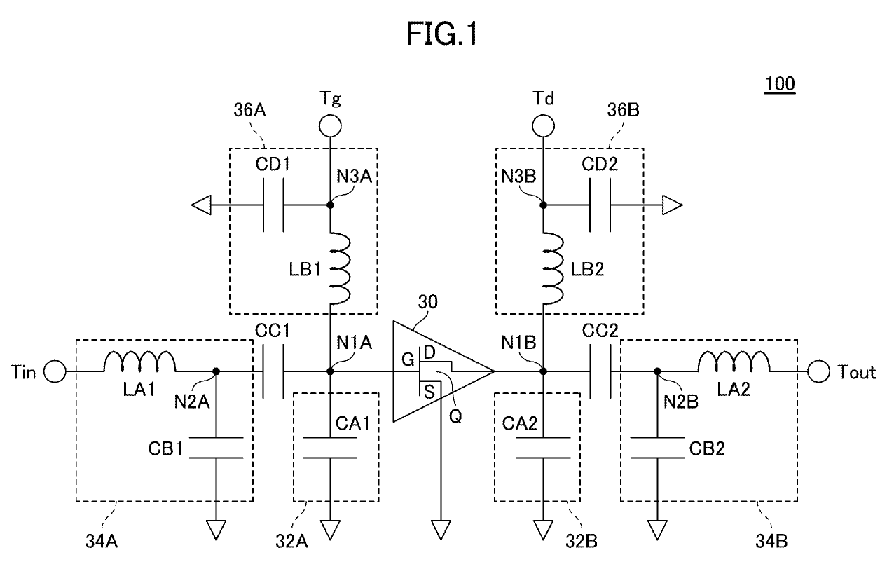

FIG. 1 is a circuit diagram of a high frequency device according to a first embodiment. As shown in FIG. 1, a high frequency device 100 includes an amplifier 30, harmonic control circuits 32A and 32B, matching circuits 34A and 34B, and bias circuits 36A and 36B. The amplifier 30 includes a transistor Q. The transistor Q is, for example, a field effect transistor (FET), and includes a source S, a gate G, and a drain D. The source S is electrically connected to the ground, and a reference potential such as a ground potential is supplied to the source S. The gate G is electrically connected to a node N1A. The drain D is electrically connected to a node N1B.

The harmonic control circuit 32A includes a capacitor CA1. The capacitor CA1 is shunt-connected to the node N1A. The matching circuit 34A includes an inductor LA1 and a capacitor CB1. The inductor LA1 electrically connects an input terminal Tin and a node N2A. The capacitor CB1 is shunt-connected to the node N2A. A capacitor CC1 is electrically connected between the nodes N1A and N2A. The bias circuit 36A includes an inductor LB1 and a capacitor CD1. The inductor LB1 electrically connects the node N1A and a node N3A. The capacitor CD1 is shunt-connected to the node N3A. A bias terminal Tg is electrically connected to the node N3A.

The harmonic control circuit 32B includes a capacitor CA2. The capacitor CA2 is shunt-connected to the node N1B. The matching circuit 34B includes an inductor LA2 and a capacitor CB2. The inductor LA2 electrically connects an output terminal Tout and a node N2B. The capacitor CB2 is shunt-connected to the node N2B. The capacitor CC2 is electrically connected between the nodes N1B and N2B. The bias circuit 36B includes an inductor LB2 and a capacitor CD2. The inductor LB2 electrically connects the node N1B and a node N3B. The capacitor CD2 is shunt-connected to the node N3B. A bias terminal Td is electrically connected to the node N3B.

A high frequency signal is input to the input terminal Tin. When the high frequency device 100 is used in a base station of mobile communications, the frequency of the high frequency signal is, for example, 0.5GHz to 20GHz. The matching circuit 34A matches the impedance of the matching circuit 34A as viewed from the input terminal Tin with the impedance of the amplifier 30 as viewed from the matching circuit 34A at the frequency of the high frequency signal. The capacitor CC1 is a capacitor for blocking a direct current (DC) and passes the high frequency signal and blocks the direct current. The harmonic control circuit 32A passes a harmonic (for example, a second harmonic, a third harmonic, or a fourth harmonic or a higher harmonic) of the high frequency signal transmitted through the node N1A to the ground but does not pass the high frequency signal transmitted through the node N1A to the ground. Thus, the harmonic of the signal transmitted through the node N1A is suppressed. The bias circuit 36A supplies a bias voltage Vg supplied to the bias terminal Tg to the amplifier via the node N1A, and reduces leakage of a high frequency signal transmitted through the node N1A to the bias terminal Tg. The amplifier 30 amplifies the high frequency signal input from the node N1A and outputs the amplified high frequency signal to the node N1B.

The harmonic control circuit 32B passes a harmonic of the high frequency signal transmitted through the node N1B to the ground, but does not pass the high frequency signal transmitted through the node N1B to the ground. As a result, the harmonic of the signal transmitted through the node N1B is suppressed. The bias circuit 36B supplies a bias voltage Vd supplied to the bias terminal Td to the amplifier via the node N1B and reduces leakage of a high frequency signal transmitted through the node N1B to the bias terminal Td. The capacitor CC2 is a capacitor for blocking a direct current and passes the high frequency signal and blocks the direct current. The matching circuit 34B matches the impedance of the matching circuit 34B as viewed from the amplifier 30 with the impedance of the output terminal Tout as viewed from the matching circuit 34B at the frequency of the high frequency signal. The output terminal Tout outputs the high frequency signal amplified by the amplifier 30.

The circuit configurations of the harmonic control circuits 32A and 32B, the matching circuits 34A and 34B, and the bias circuits 36A and 36B are not limited to those shown in FIG. 1, and can be designed as appropriate so as to perform the functions of the respective circuits. It is sufficient that either the harmonic control circuit 32A or 32B is provided.

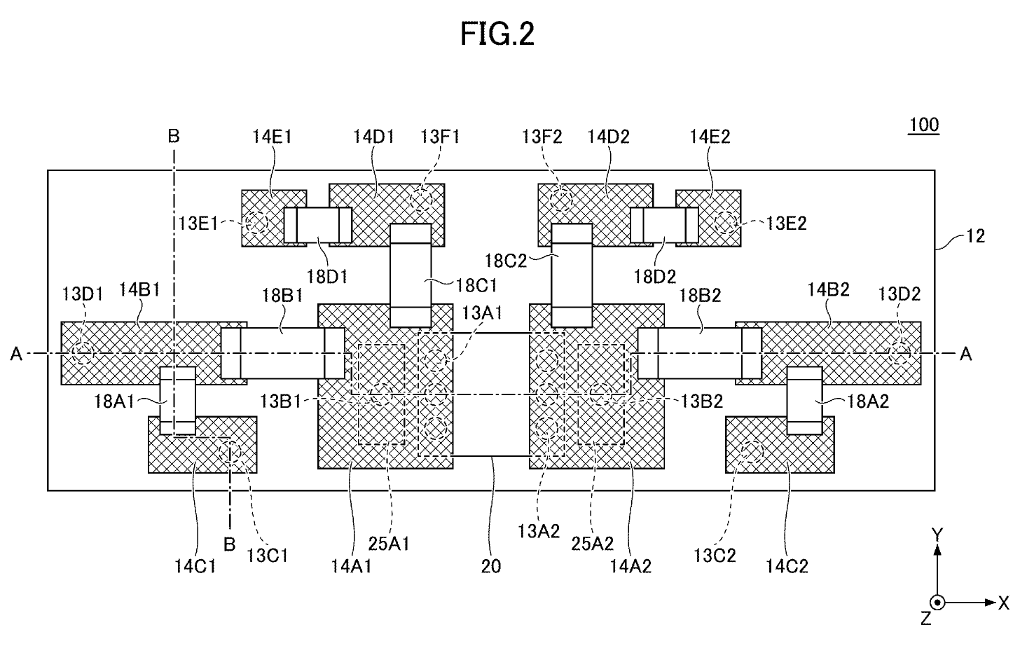

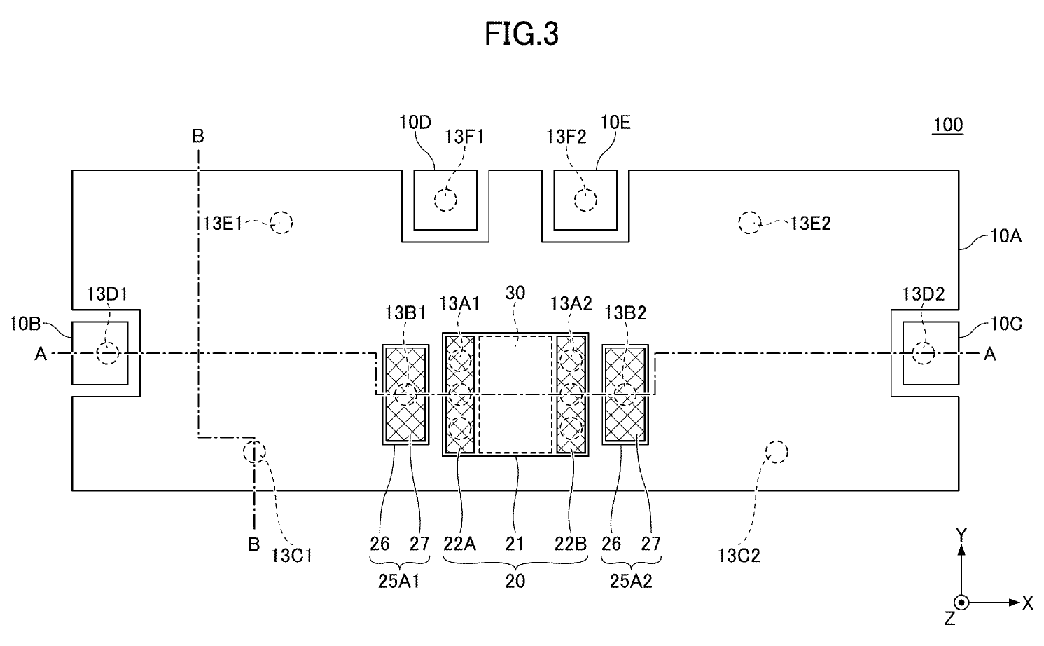

Each of FIGS. 2 and 3 is a plan view of a high frequency device according to the first embodiment. FIG. 2 is a plan view showing mainly wiring layers 14A1 to 14E1, 14A2 to 14E2, electronic components 18A1 to 18D1 and 18A2 to 18D2. FIG. 3 is a plan view mainly showing a semiconductor chip 20, passive chips 25A1 and 25A2, a base 10A, and terminals 10B to 10E. In FIGS. 2 and 3, through electrodes 13A1 to 13F1 and 13A2 to 13F2 are shown by dashed lines.

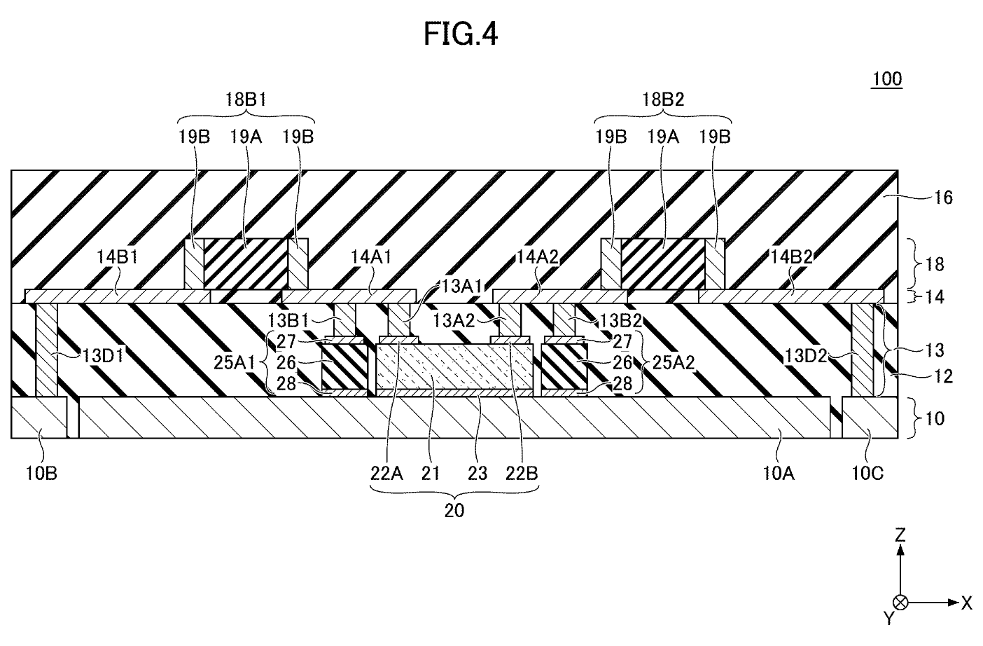

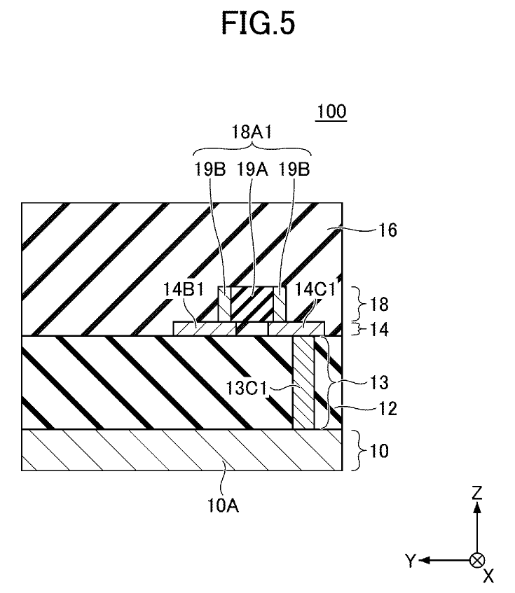

FIG. 4 is an A-A cross-sectional view of FIGS. 2 and 3. FIG. 5 is a B-B cross-sectional view of FIGS. 2 and 3. A thickness direction of the base 10A is defined as the Z direction, a direction from the terminal 10B to the terminal 10C is defined as the X direction, and a direction orthogonal to the X direction and the Z direction is defined as the Y direction.

As shown in FIGS. 4 and 5, the semiconductor chip 20 and the passive chips 25A1 and 25A2 are mounted on a lead frame 10. An insulating layer 12 is provided on the lead frame 10 so as to cover the semiconductor chip 20 and the passive chips 25A1 and 25A2. A wiring layer 14 is provided on the insulating layer 12. A through electrode 13 penetrates the insulating layer 12. A part of the through electrode 13 electrically connects the wiring layer 14 and the lead frame 10. Other parts of the through electrode 13 electrically connect the wiring layer 14 to the semiconductor chip 20, the passive chip 25A1, and the passive chip 25A2. An electronic component 18 is mounted on the insulating layer 12 and electrically connected to the wiring layer 14. An insulating layer 16 is provided on the insulating layer 12 so as to cover the electronic component 18. The electronic component 18 is, for example, a surface mount device (SMD), and is a capacitor or an inductor. The electronic component 18 has a body 19A and an electrode 19B. The electrode 19B is bonded onto the wiring layer 14 with an electrically conductive bonding member interposed therebetween. As a result, the wiring layer 14 and the electrode 19B have the same potential.

As shown in FIGS. 2 to 5, the lead frame 10 has the base 10A and the terminals 10B to 10E. The base 10A and the terminals 10B to 10E are electrically isolated from each other with the insulating layer 12 interposed therebetween. The semiconductor chip 20 and the passive chips 25A1 and 25A2 are mounted on the base 10A. The semiconductor chip 20 includes the amplifier 30, pads 22A and 22B, and an electrode 23. The pads 22A and 22B are provided on an upper surface of a substrate 21. The electrode 23 is provided on a lower surface of the substrate 21. The source S, the gate G, and the drain D of the transistor Q of the amplifier 30 are electrically connected to the electrode 23, the pad 22A and the pad 22B, respectively.

Each of the passive chips 25A1 and 25A2 includes a dielectric substrate 26 and electrodes 27 and 28. The electrode 27 is provided on an upper surface of the dielectric substrate 26, and the electrode 28 is provided on a lower surface of the dielectric substrate 26. The electrodes 23 and 28 are connected to the base 10A with an electrically conductive bonding member, which is formed by sintering an electrically conductive paste, interposed therebetween. When the reference potential is supplied to the base 10A, the reference potential is supplied to the electrodes 23 and 28.

The through electrodes 13A1 to 13F1 and 13A2 to 13F2 penetrate the insulating layer 12. The wiring layers 14A1 to 14E1 and 14A2 to 14E2 are provided on the insulating layer 12 and are electrically isolated from each other.

The through electrode 13A1 electrically connects the pad 22A of the semiconductor chip 20 and the wiring layer 14A1. The through electrode 13B1 electrically connects the electrode 27 of the passive chip 25A1 and the wiring layer 14A1. The through electrode 13C1 electrically connects the wiring layer 14C1 and the base 10A. The through electrode 13D1 electrically connects the wiring layer 14B1 and the terminal 10B. The through electrode 13E1 electrically connects the wiring layer 14E1 and the base 10A. The through electrode 13F1 electrically connects the wiring layer 14D1 and the terminal 10D.

The through electrode 13A2 electrically connects the pad 22B of the semiconductor chip 20 and the wiring layer 14A2. The through electrode 13B2 electrically connects the electrode 27 of the passive chip 25A2 and the wiring layer 14A2. The through electrode 13C2 electrically connects the wiring layer 14C2 and the base 10A. The through electrode 13D2 electrically connects the wiring layer 14B2 and the terminal 10C. The through electrode 13E2 electrically connects the wiring layer 14E2 and the base 10A. The through electrode 13F2 electrically connects the wiring layer 14D2 and the terminal 10E.

The electronic component 18A1 is a capacitor, and a first end and a second end of the electronic component 18A1 are electrically connected to the wiring layers 14B1 and 14C1, respectively. The electronic component 18B1 is a capacitor, and a first end and a second end of the electronic component 18B1 are electrically connected to the wiring layers 14A1 and 14B1, respectively. The electronic component 18C1 is an inductor, and a first end and a second end of the electronic component 18C1 are electrically connected to the wiring layers 14A1 and 14D1, respectively. The electronic component 18D1 is a capacitor, and a first end and a second end of the electronic component 18D1 are electrically connected to the wiring layers 14E1 and 14D1, respectively.

The electronic component 18A2 is a capacitor, and a first end and a second end of the electronic component 18A2 are electrically connected to the wiring layers 14B2 and 14C2, respectively. The electronic component 18B2 is a capacitor, and a first end and a second end of the electronic component 18B2 are electrically connected to the wiring layers 14A2 and 14B2, respectively. The electronic component 18C2 is an inductor, and a first end and a second end of the electronic component 18C2 are electrically connected to the wiring layers 14A2 and 14D2, respectively. The electronic component 18D2 is a capacitor, and a first end and a second end of the electronic component 18D2 are electrically connected to the wiring layers 14E2 and 14D2, respectively.

The semiconductor chip 20 has the amplifier 30 shown in FIG. 1. The dielectric substrate 26 and the electrodes 27 and 28 sandwiching the dielectric substrate 26 in the passive chip 25A1 correspond to the capacitor CA1, and the dielectric substrate 26 and the electrodes 27 and 28 sandwiching the dielectric substrate 26 in the passive chip 25A2 correspond to the capacitor CA2. The electronic components 18A1, 18B1, 18D1, 18A2, 18B2, and 18D2 correspond to the capacitors CB1, CC1, CD1, CB2, CC2, and CD2, respectively. The electronic components 18C1 and 18C2 correspond to the inductors LB1 and LB2, respectively. The wiring layers 14B1 and 14B2 correspond to the inductors LA1 and LA2, respectively.

The lead frame 10 is electrically conductive, is a metal plate such as a copper plate, and is plated with a silver film or the like. When the transistor Q is a gallium nitride high electron mobility transistor (GaN HEMT), the substrate 21 is, for example, a silicon carbide substrate or a sapphire substrate, and has a gallium nitride channel layer and an aluminum gallium nitride barrier layer. When the transistor Q is a laterally diffused metal oxide semiconductor (LDMOS), the substrate 21 is a silicon substrate. The pads 22A and 22B and the electrode 23 are metal layers such as gold layers. The dielectric substrate 26 is, for example, an alumina substrate or a high dielectric substrate. The electrodes 27 and 28 are metal layers such as gold layers. The insulating layers 12 and 16 are made of resin such as epoxy resin. The through electrode 13 and the wiring layer 14 are metal layers such as copper layers.

### First Comparative Embodiment

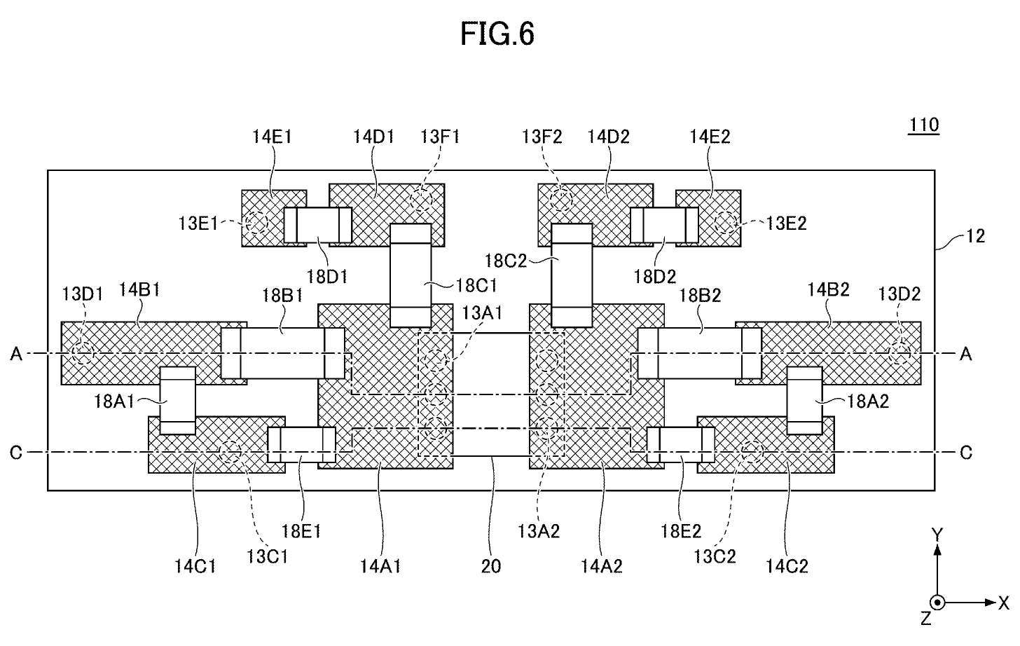

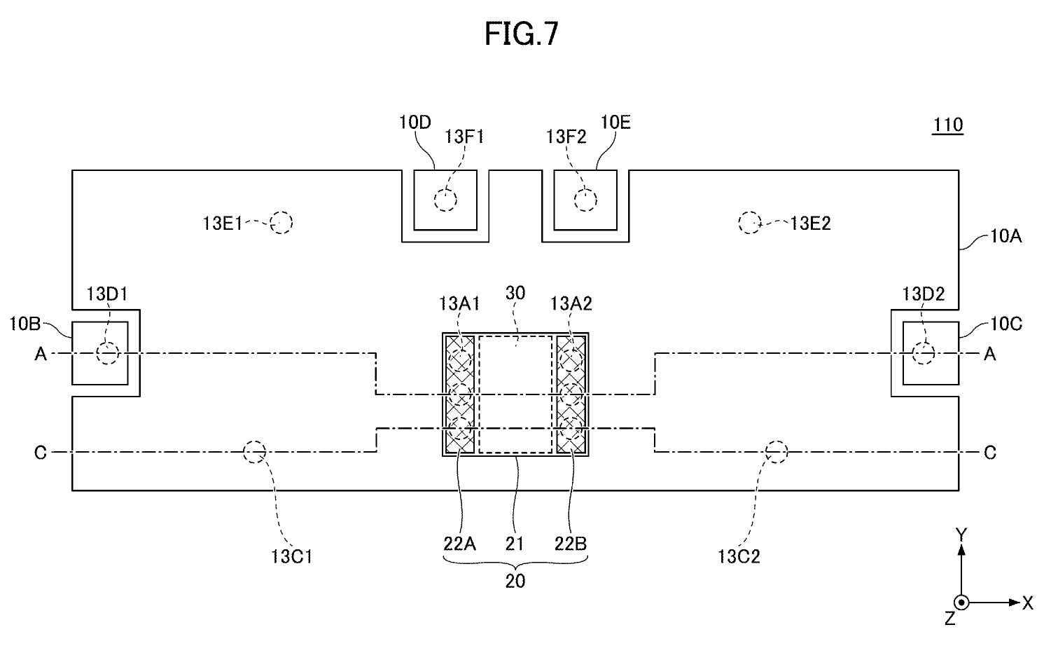

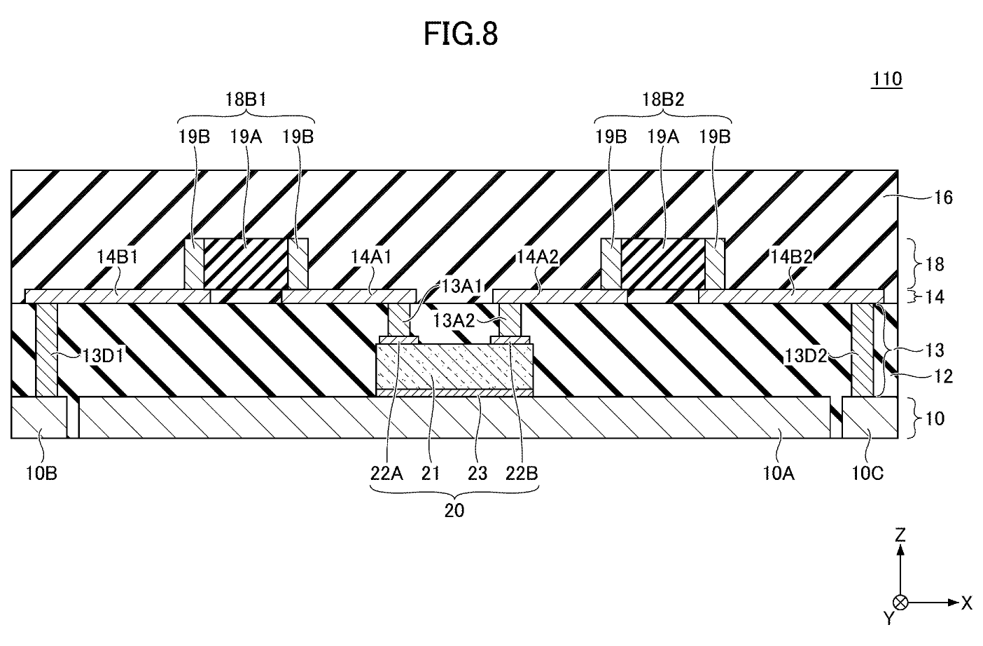

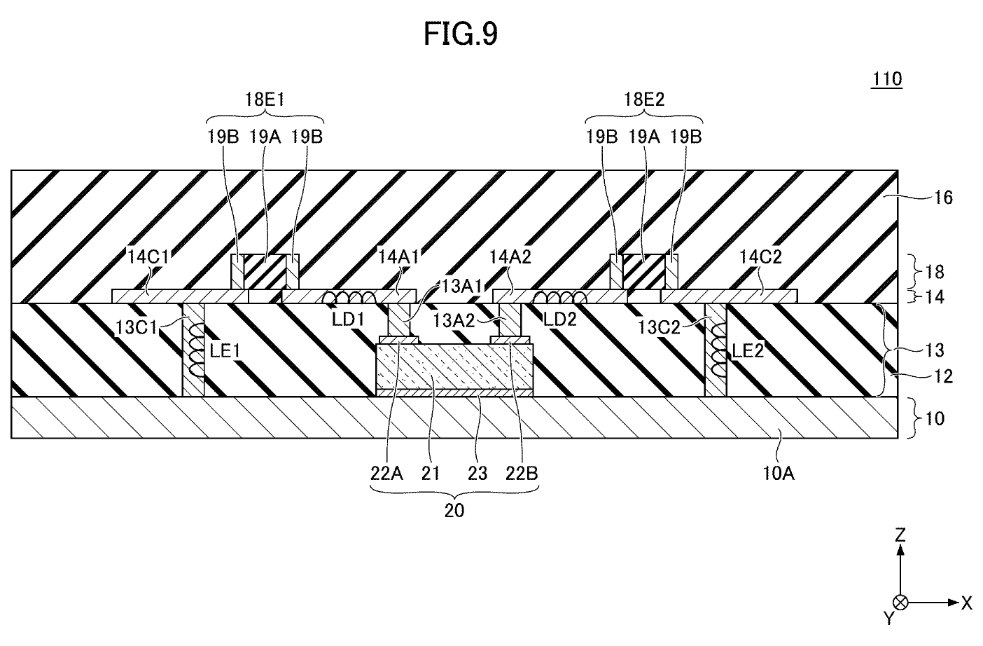

Each of FIGS. 6 and 7 is a plan view of a high frequency device according to a first comparative embodiment. FIG. 8 is an A-A cross-sectional view of FIGS. 6 and 7. FIG. 9 is a C-C cross-sectional view of FIGS. 6 and 7. As shown in FIGS. 6 to 9, a high frequency device 110 of the first comparative embodiment includes electronic components 18E1 and 18E2 but does not include the passive chips 25A1 or 25A2. The electronic component 18E1 is a capacitor, and a first end and a second end of the electronic component 18E1 are electrically connected to the wiring layers 14A1 and 14C1, respectively. The electronic component 18E2 is a capacitor, and a first end and a second end of the electronic component 18E2 are electrically connected to the wiring layers 14A2 and 14C2, respectively.

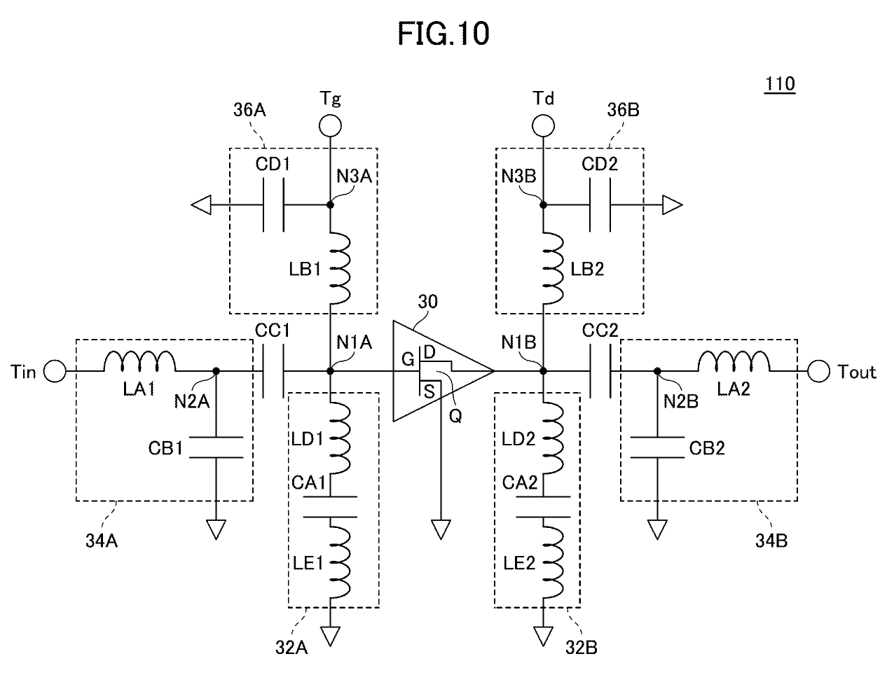

FIG. 10 is a circuit diagram of a high frequency device according to a first comparative embodiment. As shown in FIG. 10, in the high frequency device 110 of the first comparative embodiment, the harmonic control circuit 32A has inductors LD1 and LE1 and the capacitor CA1. The harmonic control circuit 32B includes inductors LD2 and LE2 and the capacitor CA2. The electronic components 18E1 and 18E2 correspond to the capacitors CA1 and CA2. The inductors LD1 and LD2 correspond to the parasitic inductances of the wiring layers 14A1 and 14A2 shown in FIG. 9, respectively. The inductors LE1 and LE2 correspond to the parasitic inductances of the through electrodes 13C1 and 13C2 in FIG. 9, respectively.

The harmonic control circuits 32A and 32B are configured to process, for example, a second harmonic having a frequency twice the frequency of the high frequency signal. The impedance of the inductor increases in proportion to the frequency. Thus, when the parasitic inductors LD1 and LE1 are connected in series to the capacitor CA1 and the parasitic inductors LD2 and LE2 are connected in series to the capacitor CA2, the high frequency characteristics of the harmonic control circuits 32A and 32B deviate from the desired characteristics and deteriorate.

In addition, when the capacitors CA1, CB1, and CD1 and the capacitors CA2, CB2, and CD2 are provided as the electronic components 18 on the insulating layer 12, the planar area of the high frequency device 100 increases.

### Description of First Embodiment

In the high frequency device 100 of the first embodiment, the harmonic control circuits 32A and 32B include the capacitors CA1 and CA2 (first capacitors) shunt-connected to lines (wiring layers 14A1 and 14A2) that are provided on the insulating layer 12 and transmit a high frequency signal. The capacitors CA1 and CA2 are mounted on the base 10A having an electrical conductivity. In this manner, by providing the harmonic control circuits 32A and 32B on the base 10A, the inductances of the parasitic inductors LD1, LE1, LD2, and LE2 of the first comparative embodiment can be reduced. Thus, the high frequency characteristics of the harmonic control circuits 32A and 32B can be improved. Further, by mounting the capacitors CA1 and CA2 on the base 10A, the electronic components 18E1 and 18E2 in FIG. 6 can be reduced, and the high frequency device 100 can be downsized.

The harmonic control circuits 32A and 32B do not pass a high frequency signal of the operation band of the amplifier 30 to the base 10A, and pass a harmonic (for example, a second harmonic) of the operation band to the base 10A. From this viewpoint, an absolute value |Z1| of an impedance Z1 at the center frequency f0 of the operation band when the passive chip 25A1 is viewed from the wiring layer 14A1 is larger than an absolute value |Z2| of an impedance Z2 at the frequency 2 × f0 when the passive chip 25A1 is viewed from the wiring layer 14A1. The absolute value |Z1| of the impedance Z1 at the center frequency f0 of the operation band when the passive chip 25A2 is viewed from the wiring layer 14A2 is larger than the absolute value |Z2| of the impedance Z2 at the frequency 2 × f0 when the passive chip 25A2 is viewed from the wiring layer 14A2. The absolute value |Z1| can be greater than or equal to twice the absolute value |Z2|.

Each of the capacitors CA1 and CA2 includes the dielectric substrate 26, the electrode 27 (first electrode) provided on the dielectric substrate 26, and the electrode 28 (second electrode) provided under the dielectric substrate 26 and bonded onto the base 10A. The through electrodes 13B1 and 13B2 (first through electrodes) electrically connect the wiring layers 14A1 and 14A2 (first wiring layers) to the electrode 27, respectively. In this manner, the capacitors CA1 and CA2 are provided in the passive chips 25A1 and 25A2. In the first comparative embodiment, as shown in FIG. 9, the parasitic inductors LE1 and LE2 of the through electrodes 13C1 and 13C2 are connected between the capacitors CA1 and CA2 and the base 10A. In contrast, in the first embodiment, as shown in FIG. 4, the electrodes 28 of the capacitors CA1 and CA2 are bonded to the base 10A by a bonding member. This can reduce the inductances of the parasitic inductors LE1 and LE2 of the first comparative embodiment. Lengths of the through electrodes 13B1 and 13B2 in the Z direction are smaller than those of the through electrodes 13C1 and 13C2 in the first comparative embodiment. Thus, the parasitic inductance added to the capacitors CA1 and CA2 is lower than that of the first comparative embodiment. This makes it possible to improve the high frequency characteristics of the harmonic control circuits 32A and 32B.

As shown in FIG. 4, the through electrodes 13A1 and 13A2 (second through electrodes) penetrate the insulating layer 12 and electrically connect the wiring layers 14A1 and 14A2 to the pads 22A and 22B, respectively. In this manner, the passive chips 25A1 and 25A2 are connected to the wiring layers 14A1 and 14A2 to which the semiconductor chip 20 is electrically connected, respectively, so that the electrical distance between the semiconductor chip 20 and the passive chip 25A1 and the electrical distance between the semiconductor chip 20 and the passive chip 25A2 can be shortened. This can reduce the inductances of the parasitic inductors LD1 and LD2 shown in FIG. 9 of the first comparative embodiment.

As shown in FIG. 2, when viewed in the Z direction, the passive chips 25A1 and 25A2 overlap the wiring layers 14A1 and 14A2 respectively, and the passive chip 25A1 is not provided outside the wiring layer 14A1 and the passive chip 25A2 is not provided outside the wiring layer 14A2. This enables the high frequency device 100 to be downsized. The through electrode 13B1 is provided between the through electrode 13A1 and the electronic component 18B1. The through electrode 13B2 is provided between the through electrode 13A2 and the electronic component 18B2. This can further reduce the inductances of the parasitic inductors LD1 and LD2.

As shown in FIGS. 2 and 5, the electronic components 18A1 and 18A2 corresponding to the capacitors CB1 and CB2 (second capacitors) that the matching circuits 34A and 34B respectively include are mounted on the insulating layer 12. The matching circuits 34A and 34B are impedance matching circuits for high frequency signals, and even when parasitic inductors are added to the capacitors CB1 and CB2 that are shunt-connected to the line through which the high frequency signals are transmitted, the high frequency characteristics of the matching circuits 34A and 34B are less likely to be affected. Thus, when some of the capacitors CA1, CB1, and CD1 and the capacitors CA2, CB2, and CD2 shunt-connected to the line through which the high frequency signal is transmitted are mounted on the base 10A, the capacitors CA1 and CA2 are mounted on the base 10A. Further, the capacitors CB1 and CB2 are mounted on the insulating layer 12. Thus, the capacitor mounted on the base 10A and the capacitor mounted on the insulating layer 12 can be arranged in a balanced manner, and thus the high frequency device 100 can be downsized and the high frequency characteristics can be improved.

A high frequency signal is transmitted through the wiring layers 14B1 and 14B2 (second wiring layers). The wiring layers 14C1 and 14C2 (third wiring layers) are electrically connected to the base 10A. The first ends of the electronic components 18A1 and 18A2 corresponding to the capacitors CB1 and CB2 are respectively bonded onto the wiring layers 14B1 and 14B2. The second ends of the electronic components 18A1 and 18A2 are respectively bonded onto the wiring layers 14C1 and 14C2. When the capacitors CB1 and CB2 shunt-connected to the line are mounted on the insulating layer 12, a wiring layer of a reference potential is provided as in the wiring layers 14C1 and 14C2. In order to supply the reference potential to the wiring layers 14C1 and 14C2, the through electrodes 13C1 and 13C2 are provided, and a parasitic inductor is connected between the capacitors CB1 and CB2 and the reference potential. However, since the capacitors CB1 and CB2 are capacitors for impedance matching in a high frequency signal, the parasitic inductor is less likely to affect the capacitors CB1 and CB2 than the capacitors CA1 and CA2. Thus, the capacitors CB1 and CB2 may be mounted on the insulating layer 12. Thus, the capacitors mounted on the base 10A and the capacitors mounted on the insulating layer 12 can be arranged in a balanced manner, and thus the high frequency device 100 can be downsized and the high frequency characteristics can be improved.

The first ends of the electronic components 18B1 and 18B2 corresponding to the capacitors CC1 and CC2 (third capacitors) are bonded onto the wiring layers 14A1 and 14A2, respectively. The second ends of the electronic components 18B1 and 18B2 are bonded onto the wiring layers 14B1 and 14B2, respectively. The capacitors CC1 and CC2 are connected in series to a line through which a high frequency signal is transmitted and are not shunt-connected. Even when the capacitors CC1 and CC2 are mounted on the insulating layer 12, the through electrode 13 does not become a parasitic inductor. Thus, the electronic components 18B1 and 18B2 corresponding to the capacitors CC1 and CC2 may be mounted on the insulating layer 12. In FIG. 1, the capacitor CC1 may be connected between the node N2A and the input terminal Tin. The capacitor CC2 may be connected between the node N2B and the output terminal Tout.

As described above, when some of the plurality of capacitors are mounted on the base 10A and the remaining capacitors are mounted on the insulating layer 12 for reasons such as issues in arranging the capacitors, the capacitors to be mounted on the base 10A are determined using the following priority order. First, the capacitors CA1 and CA2 used in the harmonic control circuits 32A and 32B, whose characteristics are most affected by the parasitic inductor, are mounted on the base 10A. Next, the capacitors CB1 and CB2 used for the matching circuits 34A and 34B and shunt-connected to the line are mounted on the base. The capacitors CC1 and CC2 that are not shunt-connected and the capacitors CD1 and CD2 used in the bias circuits 36A and 36B may be mounted on the insulating layer 12. This enables the high frequency device 100 to be downsized.

The capacitances of the capacitors CB1 and CB2 used in the matching circuits 34A and 34B are larger than the capacitances of the capacitors CA1 and CA2 used in the harmonic control circuits 32A and 32B, respectively. Among the capacitors CA1, CA2, CB1, and CB2 shunt-connected to a line through which a high frequency signal is transmitted, the capacitors CA1 and CA2, each having small capacitance, are mounted on the base 10A, and the capacitors CB1 and CB2, each having large capacitance, are mounted on the insulating layer 12. The capacitance of each of the capacitors CB1 and CB2 can be 1.2 times or more the capacitance of each of the capacitors CA1 and CA2. Thus, the capacitor mounted on the base 10A and the capacitor mounted on the insulating layer 12 can be arranged in a balanced manner, and thus the high frequency device 100 can be downsized and the high frequency characteristics can be improved.

### Second Embodiment

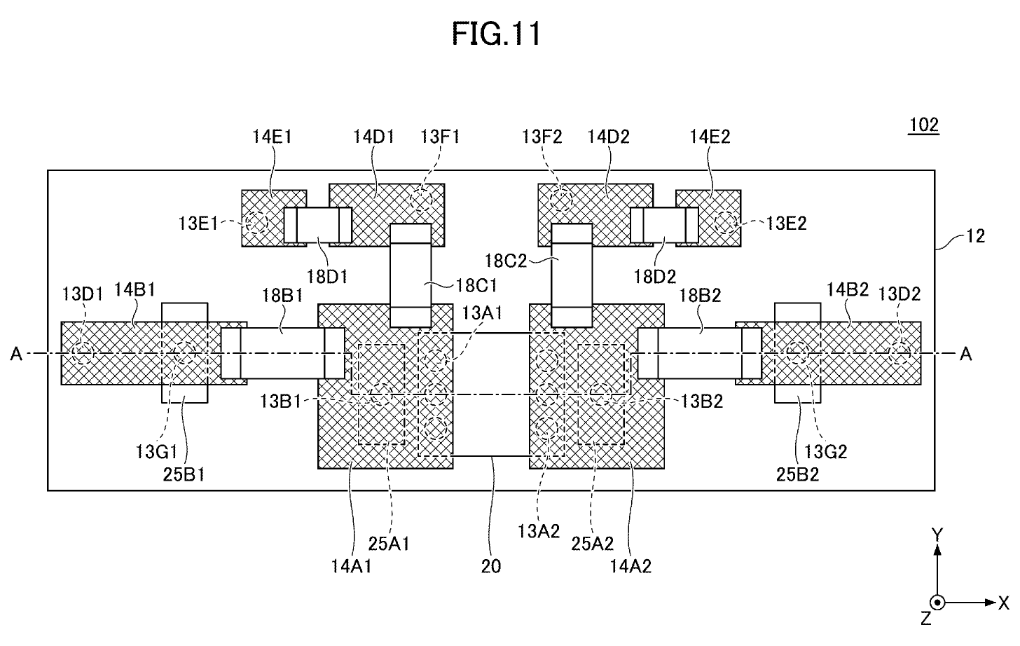

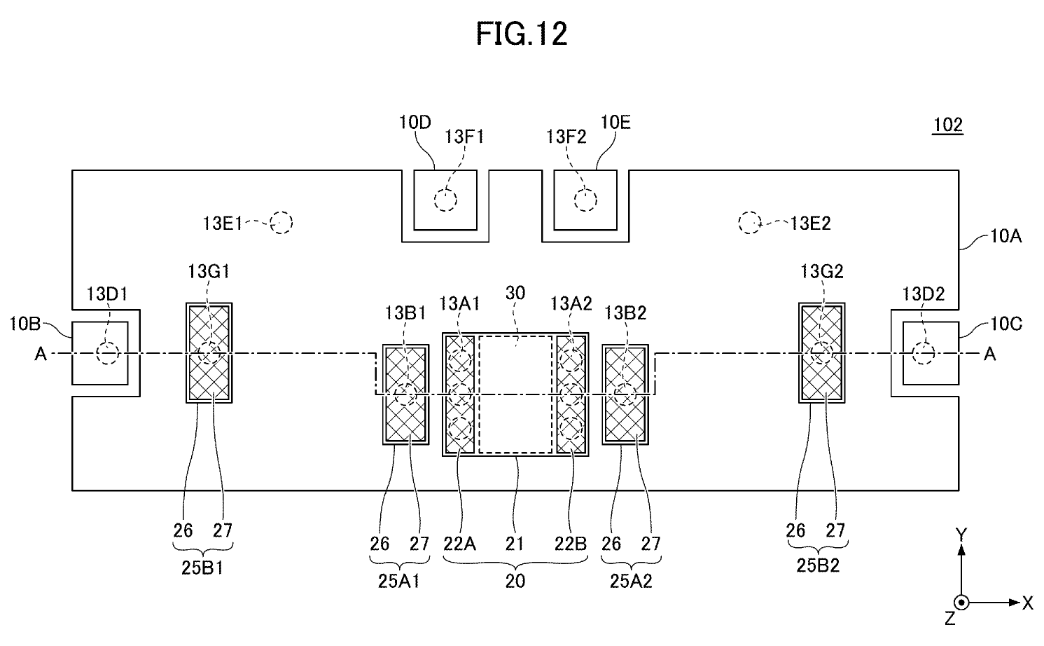

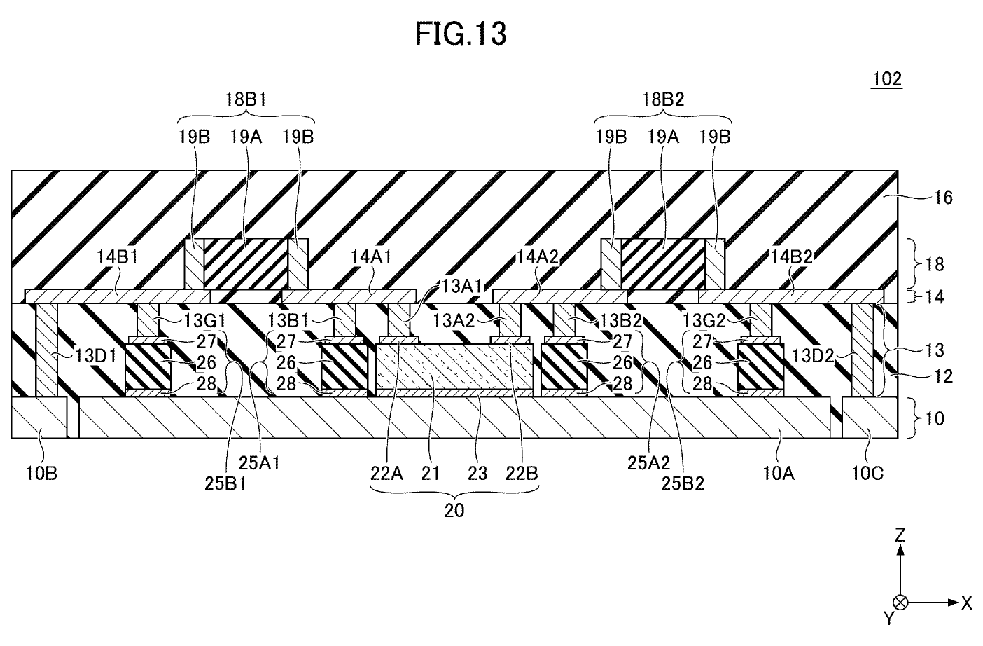

Each of FIGS. 11 and 12 is a plan view of a high frequency device according to a second embodiment. FIG. 13 is a A-A cross-sectional view of FIGS. 11 and 12. As shown in FIGS. 11 to 13, a high frequency device 102 of the second embodiment includes passive chips 25B1 and 25B2 and does not include the electronic components 18A1 or 18A2. The structures of the passive chips 25B1 and 25B2 are the same as those of the passive chips 25A1 and 25A2. Through electrodes 13G1 and 13G2 connect the electrodes 27 of the passive chips 25B1 and 25B2 to the corresponding wiring layers 14B1 and 14B2, respectively. The electrodes 28 of the passive chips 25B1 and 25B2 are bonded onto the base 10A. The other configurations are the same as those of the first embodiment, and the description thereof will be omitted.

As in the first embodiment, when the capacitors CB1 and CB2 shunt-connected to the line through which the high frequency signal is transmitted in the matching circuits 34A and 34B are the electronic components 18A1 and 18A2 on the insulating layer 12, a parasitic inductor is added. Thus, the capacitors CB1 and CB2 are the passive chips 25B1 and 25B2 mounted on the base 10A. This can reduce the inductances of the parasitic inductor component added to the capacitors CB1 and CB2. The capacitors CC1 and CC2 connected in series to the line through which the high frequency signal is transmitted are less likely to be added with a parasitic inductor even as the electronic components 18B1 and 18B2 on the insulating layer 12. Thus, the capacitors CC1 and CC2 are the electronic components 18B1 and 18B2 mounted on the insulating layer 12. Thus, the capacitor as a passive chip mounted on the base 10A and the capacitor as an electronic component mounted on the insulating layer 12 can be arranged in a balanced manner, and thus the high frequency device 102 can be downsized and the high frequency characteristics can be improved.

### Third Embodiment

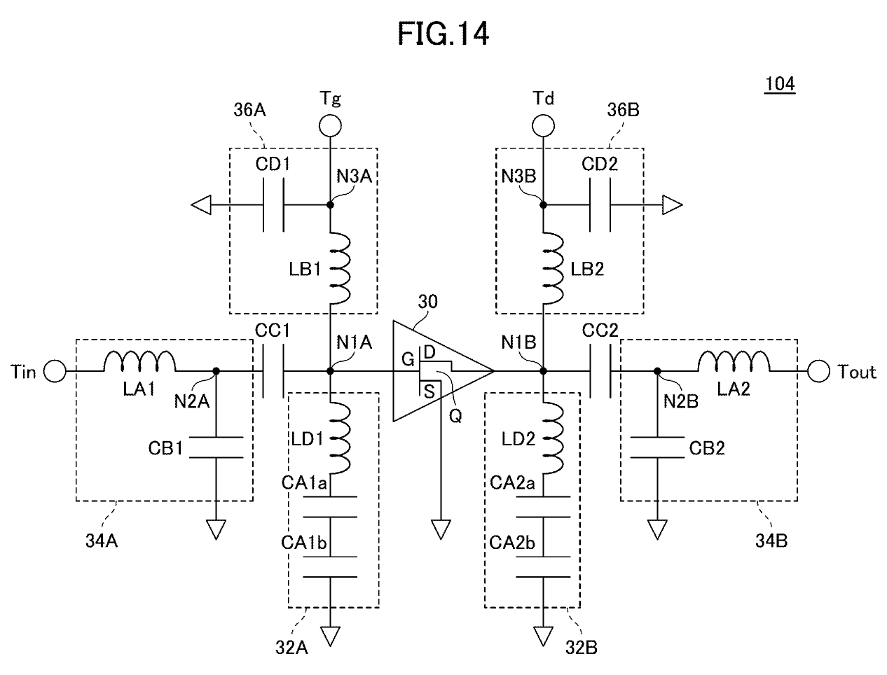

FIG. 14 is a circuit diagram of a high frequency device according to a third embodiment. As shown in FIG. 14, in a high frequency device 104, the harmonic control circuit 32A has the inductor LD1 and capacitors CA1a and CA1b connected in series between the node N1A and the ground. The harmonic control circuit 32B has the inductor LD2 and capacitors CA2a and CA2b connected in series between the node N1B and the ground.

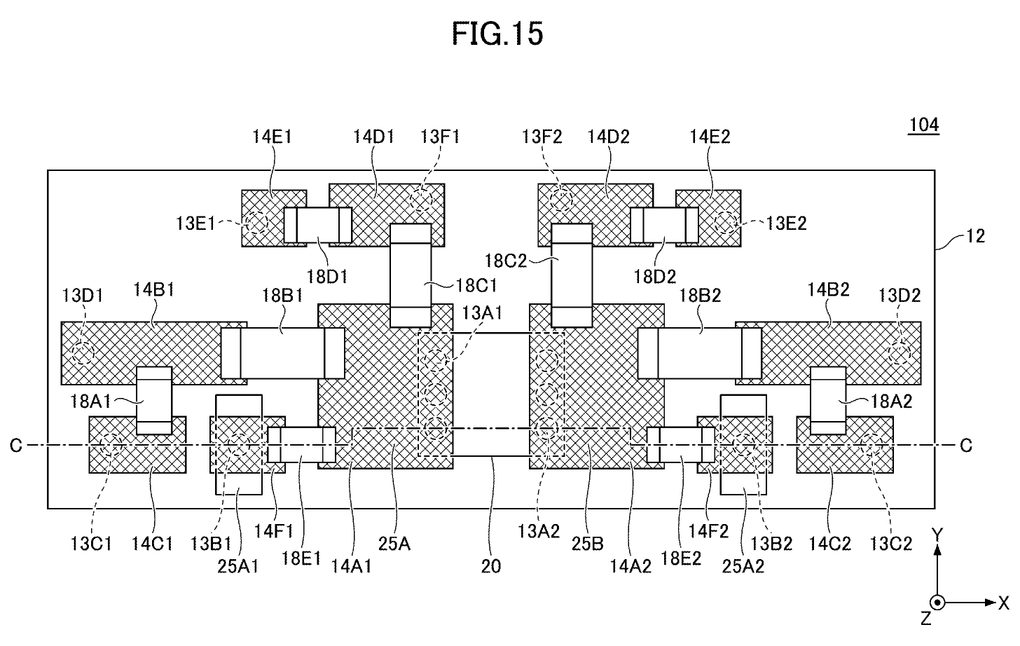

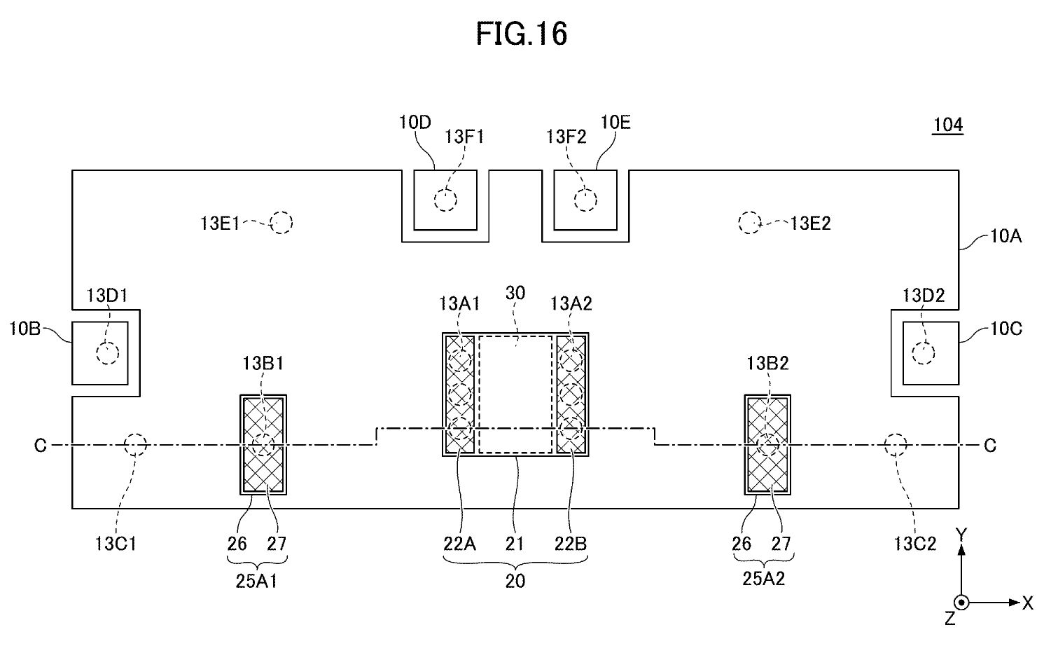

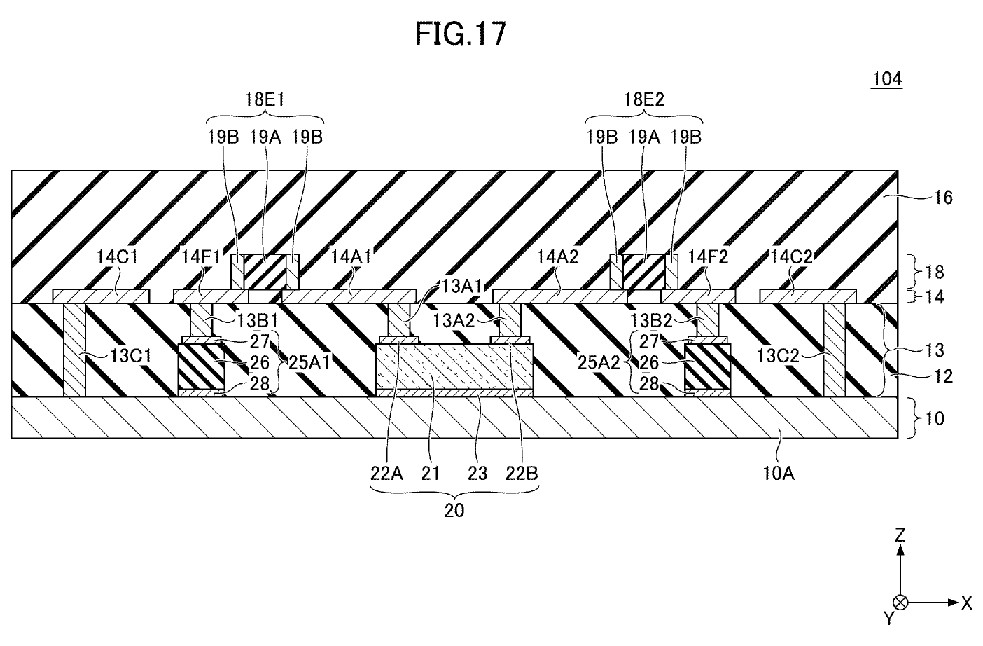

Each of FIGS. 15 and 16 is a plan view of a high frequency device according to a third embodiment. FIG. 17 is a C-C cross-sectional view of FIGS. 15 and 16. As shown in FIGS. 15 to 17, the high frequency device 104 of the third embodiment includes wiring layers 14F1 and 14F2, and the electronic components 18E1 and 18E2. The through electrode 13B1 electrically connects the electrode 27 of the passive chip 25A1 and the wiring layer 14F1. The through electrode 13B2 electrically connects the electrode 27 of the passive chip 25A2 and the wiring layer 14F2.

The electronic component 18E1 is a capacitor, and a first end and a second end of the electronic component 18E1 are electrically connected to the wiring layers 14A1 and 14F1, respectively. The electronic component 18E2 is a capacitor, and a first end and a second end of the electronic component 18E2 are electrically connected to the wiring layers 14A2 and 14F2, respectively. The other configurations are the same as those of the first embodiment, and the description thereof will be omitted.

### Second Comparative Embodiment

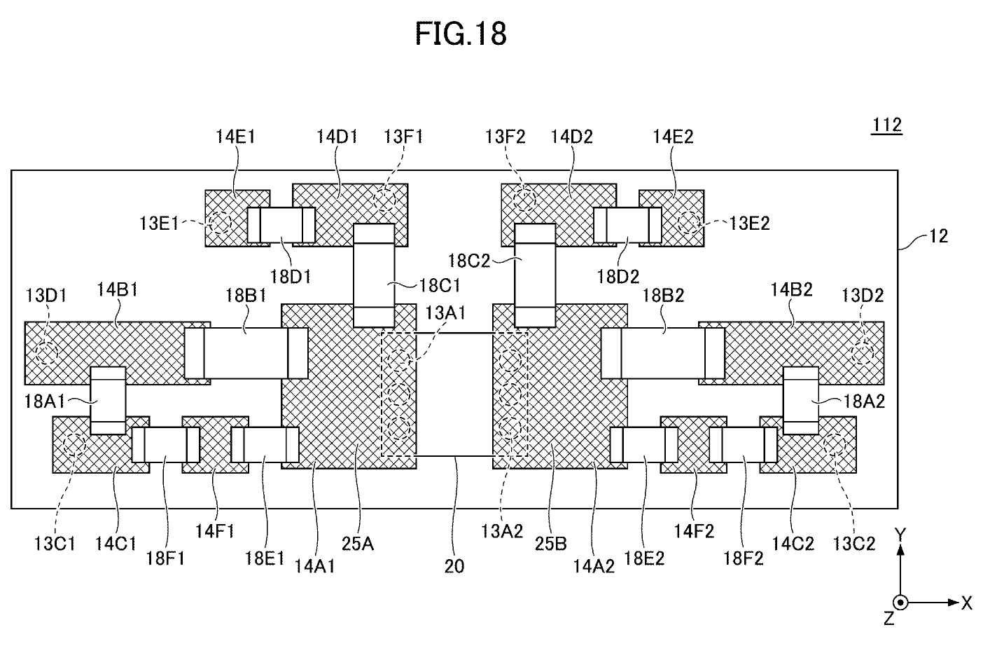

FIG. 18 is a plan view of a high frequency device according to a second comparative embodiment. As shown in FIG. 18, a high frequency device 112 of the second comparative embodiment includes electronic components 18F1 and 18F2 but does not include the passive chips 25B1 or 25B2. The electronic component 18F1 is a capacitor, and a first end and a second end of the electronic component 18F1 are electrically connected to the wiring layers 14C1 and 14F1, respectively. The electronic component 18F2 is a capacitor, and the first end and the second end of the electronic component 18F2 are electrically connected to the wiring layers 14C2 and 14F2, respectively. The other configurations are the same as those of the third embodiment.

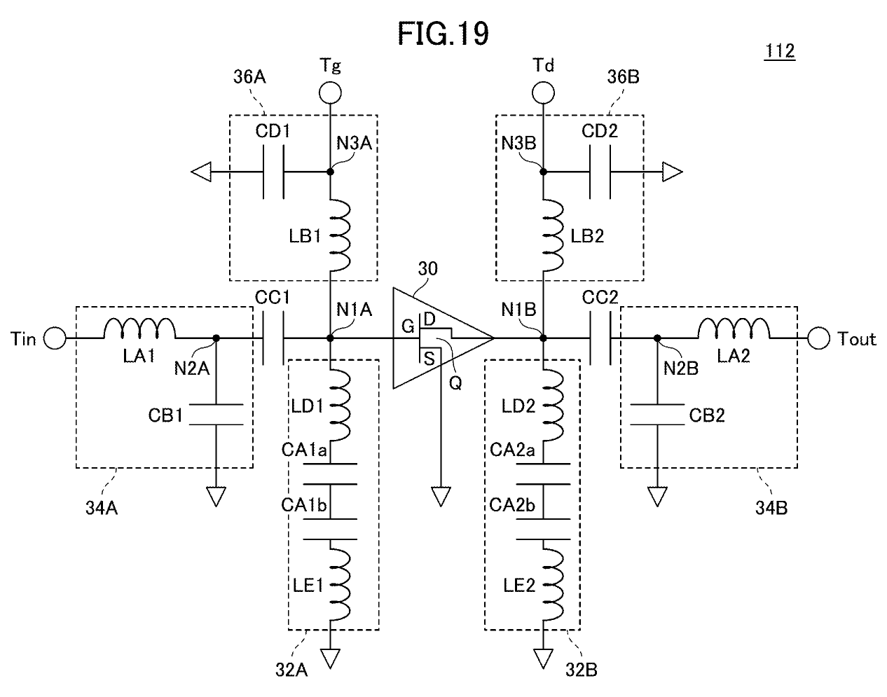

FIG. 19 is a circuit diagram of a high frequency device according to a second comparative embodiment. As shown in FIG. 19, in the high frequency device 112 of the second comparative embodiment, the inductor LE1 is connected between the capacitor CA1b and the ground, and the inductor LE2 is connected between the capacitor CA2b and the ground. The inductors LE1 and LE2 correspond to the parasitic inductances of the through electrodes 13C1 and 13C2 shown in FIG. 9, respectively. When the parasitic inductor LE1 is connected in series to the capacitor CA1b and the parasitic inductor LE2 is connected in series to the capacitor CA2b, the high frequency characteristics of the harmonic control circuits 32A and 32B deviate from the desired characteristics.

### Description of Third Embodiment

As in the high frequency device 104 of the third embodiment and the high frequency device 112 of the second comparative embodiment, the harmonic control circuits 32A and 32B may include a plurality of capacitors connected in series between the line through which the high frequency signal is transmitted and the base 10A. The reason for connecting the plurality of capacitors in series is to ensure a withstand voltage. In the high frequency device 112 of the second comparative embodiment, the capacitors CA1b and CA2b are the electronic components 18F1 and 18F2 mounted on the insulating layer 12, respectively. In this case, the parasitic inductors LE1 and LE2 caused by the through electrodes 13C1 and 13C2 are connected between the capacitors CA1b and CA2b and the base 10A, respectively. Thus, as in the high frequency device 104 of the third embodiment, the capacitor CA1b closest to the base 10A in the electrical path among the capacitors CA1a and CA1b is the passive chip 25A1. The capacitor CA2b closest to the base 10A in the electrical path among the capacitors CA2a and CA2b is the passive chip 25A2. This can reduce the inductances of the parasitic inductors LE1 and LE2. Thus, the capacitor mounted on the base 10A and the capacitor mounted on the insulating layer 12 can be arranged in a balanced manner, and thus the high frequency device 104 can be downsized and the high frequency characteristics can be improved.

The capacitors CA1a and CA2a other than the capacitors CA1b and CA2b, even as the electronic components 18E1 and 18E2 mounted on the insulating layer 12 respectively, are not connected to the parasitic inductors caused by the through electrode 13. As in the inductors LD1 and LD2, the inductance component caused by the wiring layers 14A1 and 14A2 is smaller than the inductance component caused by the through electrode 13. Thus, the capacitors CA1a and CA2a are respectively the electronic components 18E1 and 18E2 mounted on the insulating layer 12. Thus, the capacitor that is a passive chip mounted on the base 10A and the capacitor that is an electronic component mounted on the insulating layer 12 can be arranged in a balanced manner, and thus the high frequency device 104 can be downsized and the high frequency characteristics can be improved.

In the case of including the capacitors CA1a, CA1b, CA2a, and CA2b as in the third embodiment, the capacitors CB1 and CB2 may be the passive chips 25B1 and 25B2 mounted on the base 10A as in the second embodiment, respectively.

In the first embodiment to the third embodiment, an example in which the semiconductor chip 20 includes an amplifier that amplifies a high frequency signal has been described, but the semiconductor chip 20 may process a high frequency signal.

### Fourth Embodiment

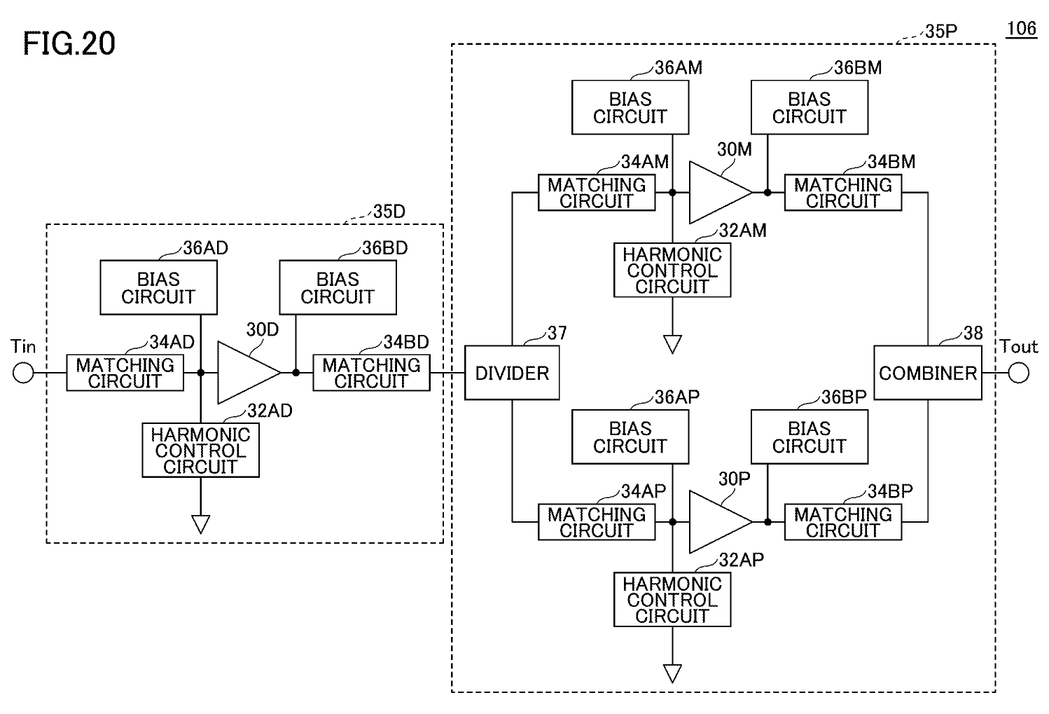

The fourth embodiment is an example in which the high frequency device of the first embodiment to the third embodiment is used for a high frequency power amplifier circuit of a base station of mobile communication. FIG. 20 is a circuit diagram of an amplifier circuit according to a fourth embodiment.

As shown in FIG. 20, an amplifier circuit 106 of the fourth embodiment includes a driver amplifier circuit 35D and a Doherty amplifier circuit 35P. The driver amplifier circuit 35D includes an amplifier 30D, a harmonic control circuit 32AD, matching circuits 34AD and 34BD, and bias circuits 36AD and 36BD. The functions of the amplifier 30D, the harmonic control circuit 32AD, the matching circuits 34AD and 34BD, and the bias circuits 36AD and 36BD are the same as those of the first embodiment to the third embodiment. The circuit configurations of the matching circuits 34AD and 34BD and the bias circuits 36AD and 36BD may be different from those of the first embodiment to the third embodiment. The driver amplifier circuit 35D amplifies a high frequency signal input to the input terminal Tin and outputs the amplified high frequency signal to the Doherty amplifier circuit 35P.

The Doherty amplifier circuit 35P includes amplifiers 30M and 30P, harmonic control circuits 32AM and 32AP, matching circuits 34AM, 34BM, 34AP, and 34BP, bias circuits 36AM, 36BM, 36AP, and 36BP, a divider 37, and a combiner 38. The functions of the amplifiers 30M and 30P, the harmonic control circuits 32AM and 32AP, the matching circuits 34AM, 34BM, 34AP, and 34BP, and the bias circuits 36AM, 36BM, 36AP, and 36BP are the same as those of the first embodiment to the third embodiment. The circuit configurations of the amplifiers 30M and 30P, the harmonic control circuits 32AM and 32AP, the matching circuits 34AM, 34BM, 34AP, and 34BP, and the bias circuits 36AM, 36BM, 36AP, and 36BP may be different from those of the first embodiment to the third embodiment.

The divider 37 distributes the high frequency signal output from the driver amplifier circuit 35D to the amplifiers 30M and 30P. The combiner 38 combines the high frequency signal amplified by the amplifier 30M and the high frequency signal amplified by the amplifier 30P and outputs the combined high frequency signal to the output terminal Tout as an output signal. The amplifier 30M is a main amplifier and operates in class A or AB. The amplifier 30P is a peak amplifier and operates in class C. When the power of the input high frequency signal is small, the amplifier 30M amplifies the high frequency signal, and the amplifier 30P does not amplify the high frequency signal. When the power of the input high frequency signal is large, the amplifiers 30M and 30P amplify the high frequency signal.

As an example, the capacitance of the capacitor of the harmonic control circuit 32AD in the driver amplifier circuit 35D is 0.3pF, and the capacitance of the shunt capacitor of the matching circuit 34AD is 1.2pF. In the harmonic control circuit 32AM in the Doherty amplifier circuit 35P, two capacitors are connected in series, and the capacitances of the two capacitors are each 0.6pF. The capacitance of the shunt capacitor of the matching circuit 34AM is 1.9pF. In the harmonic control circuit 32AP in the Doherty amplifier circuit 35P, two capacitors are connected in series, and the capacitances of the two capacitors are each 0.6pF. The matching circuit 34AP includes two shunt capacitors connected in parallel, and the capacitances of the two shunt capacitors are each 1.8pF.

As in the fourth embodiment, the high frequency device of the first embodiment to the third embodiment may be used for at least one amplifier circuit of the driver amplifier circuit 35D or the Doherty amplifier circuit 35P.

The embodiments disclosed herein are to be considered in all respects as illustrative and not restrictive. The scope of the present disclosure is defined by the appended claims rather than by the foregoing description, and all changes that come within the meaning and range of equivalency of the claims are intended to be embraced therein.

What is claimed is:

1. A high frequency device comprising:
a base having an electrical conductivity;
a semiconductor chip mounted on the base and configured to process a high frequency signal;
a harmonic control circuit including a first capacitor mounted on the base and configured to process a harmonic of the high frequency signal;
an insulating layer provided on the base so as to cover the semiconductor chip and the first capacitor; and
a line provided on the insulating layer and configured to transmit the high frequency signal,
wherein the first capacitor is shunt-connected to the line.

2. The high frequency device according to claim 1, further comprising:
a first wiring layer provided on the insulating layer; and
a first through electrode penetrating the insulating layer,
wherein the first capacitor includes a dielectric substrate, a first electrode provided on the dielectric substrate, and a second electrode provided under the dielectric substrate and bonded to the base, and
wherein the first wiring layer is electrically connected to the first electrode by the first through electrode.

3. The high frequency device according to claim 2, further comprising:
a second through electrode penetrating the insulating layer,
wherein the semiconductor chip includes a pad to which the high frequency signal is input or from which the high frequency signal is output, and
wherein the first wiring layer is electrically connected to the pad by the second through electrode.

4. The high frequency device according to claim 1,
wherein the harmonic control circuit includes a plurality of capacitors connected in series between the line and the base,
wherein the first capacitor is a capacitor closest to the base among the plurality of capacitors, and
wherein the plurality of capacitors include the first capacitor and one or more capacitors mounted on the insulating layer.

5. The high frequency device according to claim 1, further comprising:
an input terminal to which the high frequency signal is input;
an output terminal from which the high frequency signal processed by the semiconductor chip is output; and
a matching circuit including a second capacitor shunt-connected to the line and mounted on the insulating layer, the matching circuit being configured to match an impedance between the semiconductor chip and one of the input terminal or the output terminal at a frequency of the high frequency signal.

6. The high frequency device according to claim 5, further comprising:
a second wiring layer provided on the insulating layer and configured to transmit the high frequency signal; and
a third wiring layer provided on the insulating layer and electrically connected to the base,
wherein the second capacitor has a first end bonded onto the second wiring layer and a second end bonded onto the third wiring layer.

7. The high frequency device according to claim 1, further comprising:
an input terminal to which the high frequency signal is input;
an output terminal from which the high frequency signal processed by the semiconductor chip is output; and
a matching circuit including a second capacitor mounted on the base, the matching circuit being configured to match an impedance between the semiconductor chip and one of the input terminal or the output terminal at a frequency of the high frequency signal,
wherein the insulating layer is provided on the base so as to cover the semiconductor chip, the first capacitor, and the second capacitor.

8. The high frequency device according to claim 1, further comprising a third capacitor connected in series to the line and mounted on the insulating layer.

9. A high frequency device comprising:
a base having an electrical conductivity;
a semiconductor chip mounted on the base and configured to process a high frequency signal;
a first capacitor mounted on the base;
an insulating layer provided on the base so as to cover the semiconductor chip and the first capacitor;
a line provided on the insulating layer and configured to transmit the high frequency signal; and
a second capacitor provided on the insulating layer and having a capacitance larger than a capacitance of the first capacitor,
wherein the first capacitor and the second capacitor are shunt-connected to the line.

10. The high frequency device according to claim 1,
wherein the semiconductor chip includes an amplifier configured to amplify the high frequency signal.
